(19) United States
(12) Patent Application Publication
(10) Pub. No.: US 2026/0059747 A1
(43) Pub. Date: Feb. 26, 2026

(54) METHOD FOR MANUFACTURING SONOS MEMORY

(71) Applicant: Shanghai Huali Integrated Circuit Corporation, Shanghai (CN)

(72) Inventors: Jiaxing WANG, Shanghai (CN); Zhenghong LIU, Shanghai (CN); Ruisheng QI, Shanghai (CN); Guanqun HUANG, Shanghai (CN); Haoyu CHEN, Shanghai (CN)

(73) Assignee: Shanghai Huali Integrated Circuit Corporation, Shanghai (CN)

(21) Appl. No.: 19/244,616

(22) Filed: Jun. 20, 2025

(30) Foreign Application Priority Data
Aug. 26, 2024 (CN) 202411180344.5

(51) Int. Cl. H10B 41/35; H10D 30/01; H10D 64/66

(52) U.S. Cl. CPC H10B 41/35; H10D 30/0411; H10D 64/661

(57) ABSTRACT

Disclosed is a method for manufacturing a SONOS memory, where a polysilicon layer is first deposited on the surface of the gate dielectric layer, lithography etching is performed to form selection transistor polysilicon gates and memory transistor polysilicon gates that are spaced apart from one another, and then only a region between the selection transistor polysilicon gates adjacent to each other on the left and right is opened by lithography. In this way, during ion implantation, the ion implantation region is limited between the selection transistor polysilicon gates adjacent to each other on the left and right, and there is no excess selection transistor threshold voltage ion implantation region between the selection transistor polysilicon gate and the memory transistor polysilicon gate, avoiding a change in a selection transistor threshold voltage and avoiding a leakage, effectively improving the GIDL problem, and thereby improving device performance and reliability.

### CROSS-REFERENCE TO RELATED APPLICATIONS

This application claims priority to Chinese patent application No. 202411180344.5, filed on Aug. 26, 2024, the disclosure of which is incorporated herein by reference in its entirety.

### TECHNICAL FIELD

The present disclosure relates to the semiconductor technology, and in particular, to a method for manufacturing a SONOS memory.

### BACKGROUND

As the market demand for the level of integration of flash memory devices continues to increase, the contradiction between the reliability of data storage and the operating speed, power consumption, size, and other aspects of a conventional flash device is increasingly prominent. A silicon-oxide-nitride-oxide-silicon (SONOS) non-volatile memory is widely used in various embedded electronic products due to its characteristics such as a small cell size, a low operating voltage, and compatibility with a CMOS process. The continuous improvement of the SONOS technology promotes the development of a semiconductor memory in the directions such as miniaturization, high performance, large capacity, and low cost.

A cell structure of the silicon-oxide-nitride-oxide-silicon (SONOS) memory includes one memory transistor and one selection transistor, where gate dielectric layers of the two devices are both subjected to longitudinal electric field strengths greater than that of a CMOS device during operation of the memory, and thus the two devices each have a large gate-induced drain leakage (GIDL). N-type doing impurities of a high concentration are present in a channel of the memory transistor of the SONOS memory to form a depletion transistor, and a doping concentration of a lightly doped drain (LDD) region required by a memory cell transistor is lower than that required by the selection transistor.

A common method for manufacturing a SONOS memory includes the following steps:
I: forming a gate dielectric layer on a substrate 10, where the gate dielectric layer includes an oxide-nitride-oxide (ONO) dielectric layer 111 and a gate oxide layer 112 sequentially adjacent to and spaced apart from each other on the left and right, as shown in FIG. 1;
II: applying a photoresist (PR) to the gate dielectric layer, and performing lithography to remove the photoresist on the gate oxide layer 112 and retain the photoresist on the ONO dielectric layer 111, as shown in FIG. 2;
III: performing ion implantation, and forming a selection transistor SG threshold voltage ion implantation region 113 on the surface of the substrate 10 below the gate oxide layer 112, as shown in FIG. 3;
IV: removing the photoresist by dry etch and/or wet etch, as shown in FIG. 4;
V: growing a polysilicon layer 114 on an upper surface of the gate dielectric layer, as shown in FIG. 5;
VI: applying a photoresist (PR) on an upper surface of the polysilicon layer 114, performing lithography to remove the photoresist between each memory transistor gate region and each selection transistor gate region, so as to form memory transistor gate region photoresist strips and selection transistor gate region photoresist strips that are spaced apart from one another, where two memory transistor gate region photoresist strips spaced apart on the left and right are formed above the same oxide-nitride-oxide (ONO) dielectric layer 111, and two selection transistor gate region photoresist strips spaced apart on the left and right are formed above the same gate oxide layer 112, as shown in FIG. 6;
VII: performing etching to remove the polysilicon layer 114 exposed by the lithography in step six, as shown in FIG. 7; and
VIII: removing the photoresist by dry etch and/or wet etch to form selection transistor polysilicon gates SG and memory transistor polysilicon gates CG spaced apart from one another, where two memory transistor polysilicon gates CG spaced apart on the left and right are formed above the same oxide-nitride-oxide (ONO) dielectric layer 111, and two selection transistor polysilicon gates SG spaced apart on the left and right are formed above the same gate oxide layer 112, as shown in FIG. 8.

In the common method for manufacturing a SONOS memory, since selection transistor threshold voltage ion implantation is performed prior to depositing the polysilicon layer 114, an excess selection transistor threshold voltage ion implantation region 113 is present on the surface of the substrate 10 below the gate dielectric layer between the formed selection transistor polysilicon gate SG and memory transistor polysilicon gate CG, as shown in FIGS. 7 and 8, and the excess selection transistor threshold voltage ion implantation region 113 may result in a selection transistor gate-induced drain leakage (GIDL), causing a change in the selection transistor threshold voltage Vt and a leakage, thereby degrading device performance.

### BRIEF SUMMARY

A method for manufacturing a SONOS memory provided by the present disclosure includes the following steps:
S1: forming a gate dielectric layer on a substrate 10, where the gate dielectric layer includes an ONO dielectric layer 111 and a gate oxide layer 112 sequentially adjacent to and spaced apart from each other on the left and right;
S2: growing a polysilicon layer 114 on an upper surface of the gate dielectric layer;
S3: applying a photoresist on an upper surface of the polysilicon layer 114, then performing lithography to remove the photoresist between each memory transistor gate region and each selection transistor gate region to expose the polysilicon layer 114, so as to form memory transistor gate region photoresist strips and selection transistor gate region photoresist strips that are spaced apart from one another, where two memory transistor gate region photoresist strips spaced apart on the left and right are formed above the same ONO dielectric layer 111, and two selection transistor gate region photoresist strips spaced apart on the left and right are formed above the same gate oxide layer 112;
S4: performing etching to remove the polysilicon layer 114 exposed by the lithography;
S5: removing the photoresist to form selection transistor polysilicon gates and memory transistor polysilicon gates spaced apart from one another, where two memory transistor polysilicon gates CG spaced apart on the left and right are formed above the same ONO dielectric layer 111, and two selection transistor polysilicon gates SG spaced apart on the left and right are formed above the same gate oxide layer 112;
S6: applying a photoresist to cover upper surfaces of the polysilicon layer 114 and the gate dielectric layer, and then performing lithography to remove the photoresist between the two selection transistor polysilicon gates SG adjacent to each other on the left and right, the photoresist on a right part of the left selection transistor polysilicon gate SG, and the photoresist on a left part of the right selection transistor polysilicon gate SG, expose the gate oxide layer 112 between the two selection transistor polysilicon gates SG adjacent to each other on the left and right, and retain the photoresist between the memory transistor polysilicon gates CG, the photoresist between the memory transistor polysilicon gate CG and the selection transistor polysilicon gate SG, and the photoresist above the memory transistor polysilicon gate CG;
S7: performing ion implantation tilted by a set angle on the gate oxide layer 112 covered by no photoresist, so as to form a selection transistor threshold voltage ion implantation region 113, where the selection transistor threshold voltage ion implantation region 113 is located on the surface of the substrate 10 below the gate oxide layer 112 between the selection transistor polysilicon gates SG adjacent to each other on the left and right, below the left part of the right selection transistor polysilicon gate SG, and below the right part of the left selection transistor polysilicon gate SG;
S8: removing the photoresist; and
S9: performing a subsequent process to manufacture the SONOS memory.

In some examples, the ONO dielectric layer 111 is a silicon oxide-silicon nitride-silicon oxide stack layer.

The gate oxide layer 112 is silicon oxide.

In some examples, in step S1, a P well is formed on an upper part of the substrate 10, and the gate dielectric layer is formed on the P well of the substrate 10.

In some examples, in step S1, N-type ion implantation is performed on an upper surface of the substrate 10 below the ONO dielectric layer 111 corresponding to the memory transistor polysilicon gate.

In some examples, in step S7, P-type ion halo implantation tilted by a set angle is performed at the gate oxide layer 112 covered by no photoresist.

In some examples, a P-type ion is a boron ion.

In some examples, a depth of the P-type ion halo implantation is 150 Å-200 Å.

In some examples, energy of the P-type ion halo implantation is 8 keV-12 keV.

In some examples, a dose of the P-type ion halo implantation is 4 E13/cm²-7 E13/cm².

In some examples, the set angle is a lateral included angle of 25°-35°.

In the method for manufacturing a SONOS memory of the present disclosure, the polysilicon layer 114 is first deposited on the surface of the gate dielectric layer, lithography etching is performed to form the selection transistor polysilicon gates SG and the memory transistor polysilicon gates CG that are spaced apart from one another, and then only a region between the selection transistor polysilicon gates SG adjacent to each other on the left and right is opened by lithography. In this way, during ion implantation, the ion implantation region is limited between the selection transistor polysilicon gates SG adjacent to each other on the left and right, and there is no excess selection transistor threshold voltage ion implantation region between the selection transistor polysilicon gate SG and the memory transistor polysilicon gate CG, avoiding a change in a selection transistor threshold voltage Vt and avoiding a leakage, effectively improving the gate-induced drain leakage (GIDL) problem in a selection transistor region, and thereby improving device performance and reliability.

### BRIEF DESCRIPTION OF THE DRAWINGS

In order to more clearly explain the technical solutions of the present disclosure, the drawings required to be used in the present disclosure will be briefly described below. It is obvious that the drawings described below are merely some embodiments of the present disclosure, and those skilled in the art could also obtain other drawings on the basis of these drawings without the exercise of inventive effort.

FIGS. 1 to 8 are schematic diagrams of vertical sections in steps of a common method for manufacturing a SONOS memory.

FIGS. 9 to 15 are schematic diagrams of vertical sections in steps of an embodiment of a method for manufacturing a SONOS memory of the present disclosure.

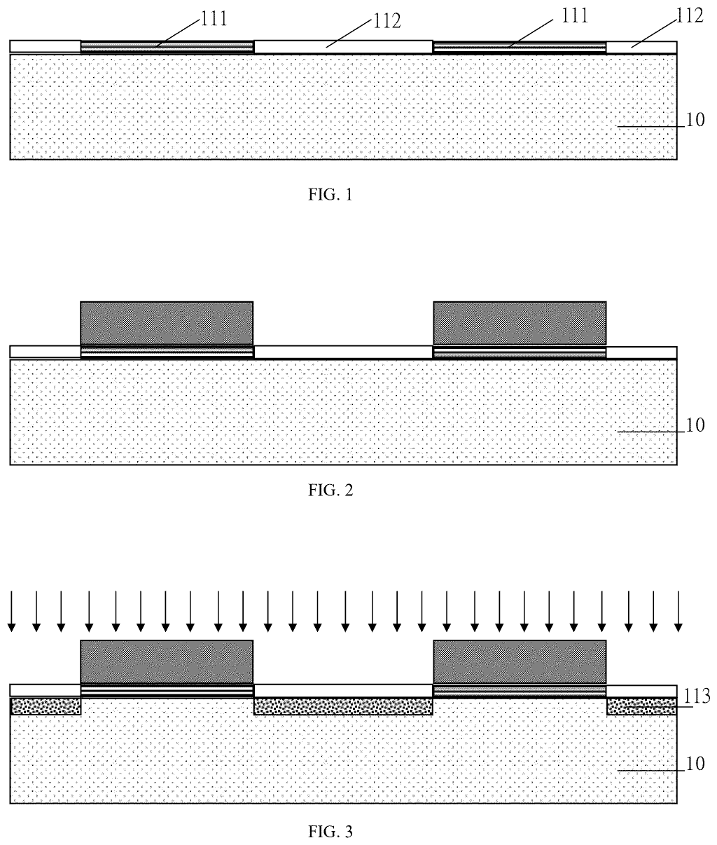

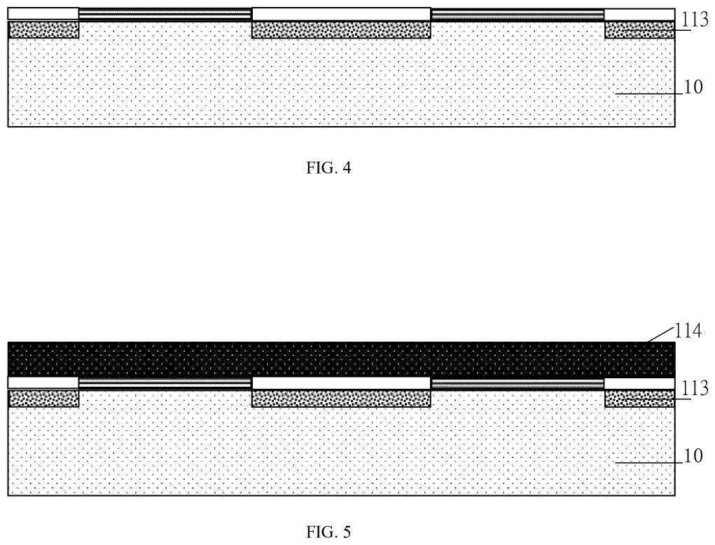

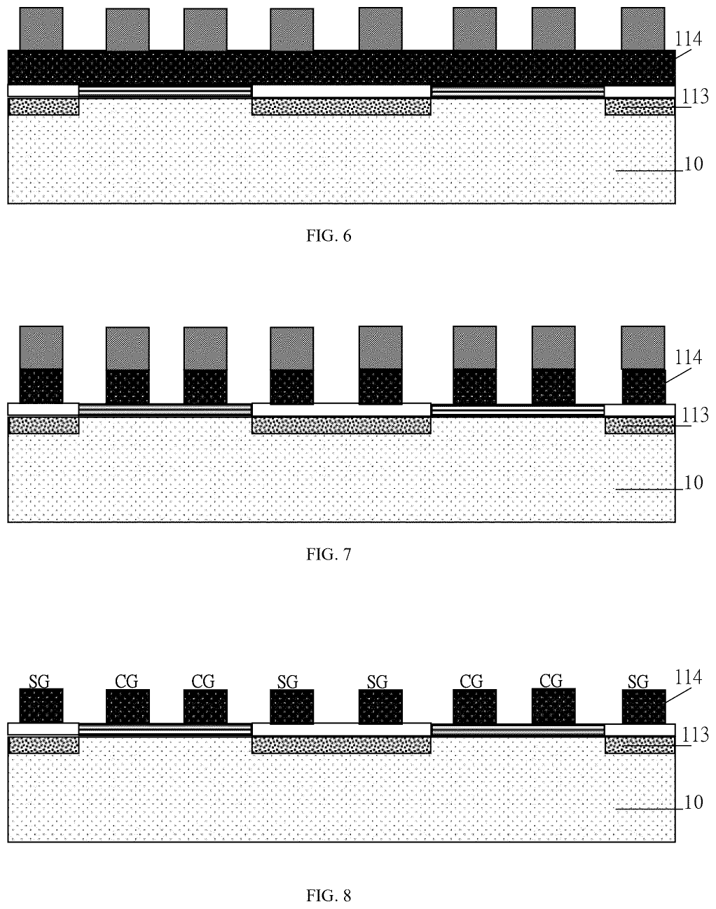

### LIST OF REFERENCE NUMERALS

10—substrate; 111—ONO dielectric layer; 112—gate oxide layer; 114—polysilicon layer; 113—selection transistor threshold voltage ion implantation region.

### DETAILED DESCRIPTION OF THE DISCLOSURE

The technical solutions in the embodiments of the present disclosure will be clearly and completely described below in conjunction with the drawings. Obviously, the described embodiments are only part of the embodiments of the present disclosure, rather than all of the embodiments. Based on the embodiments in the present disclosure, all other embodiments obtained by those skilled in the art without the practice of inventive effort shall fall into the protection scope of the present disclosure.

The “first” or “second” and similar terms used in the present disclosure do not indicate any order, quantity, or importance, but are only used to distinguish between different constituent parts. The “include” or “comprise” and similar terms mean that the components or objects in front of these terms cover the components or objects listed after the terms and equivalents thereof, but does not exclude other components or objects. The “connection” or “coupling” and similar terms are not limited to physical or mechanical connections, but may include electrical connections, whether direct or indirect. The “upper”, “lower”, “left”, “right”, “front”, “rear” and the like are only used to represent relative positional relationships, which may be changed accordingly after absolute positions of the described objects are changed.

It should be noted that the embodiments or features in the embodiments of the present disclosure can be combined with each other in the case of no conflicts.

### Embodiment I

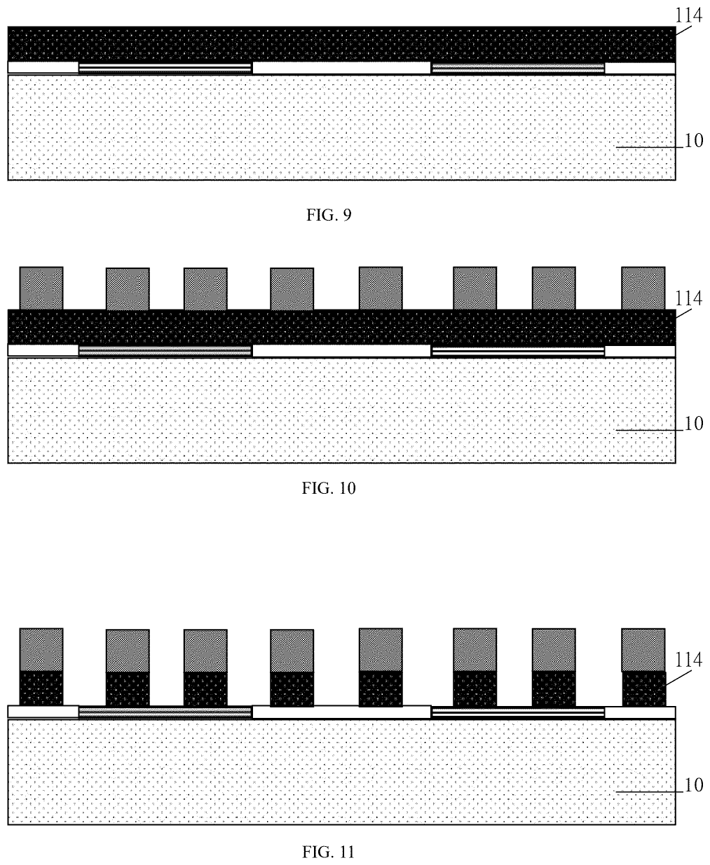

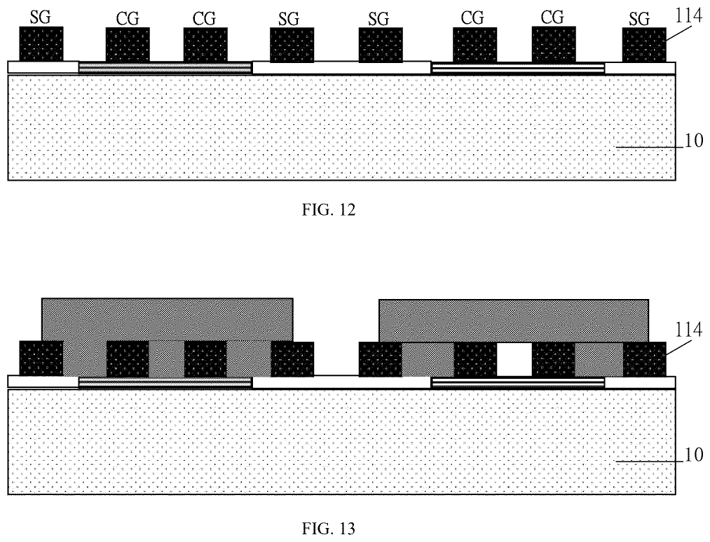

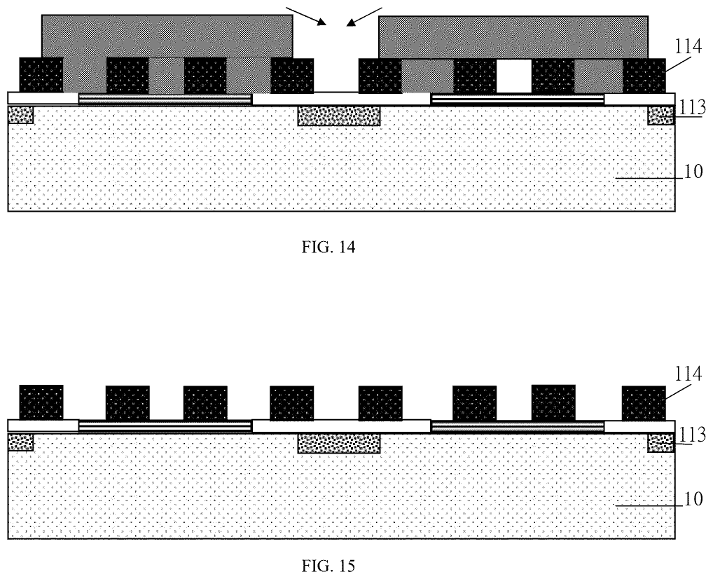

A method for manufacturing a SONOS memory includes the following steps:
S1: Form a gate dielectric layer on a substrate 10, where the gate dielectric layer includes an oxide-nitride-oxide (ONO) dielectric layer 111 and a gate oxide layer 112 sequentially adjacent to and spaced apart from each other on the left and right, as shown in FIG. 1.
S2: Grow a polysilicon layer 114 on an upper surface of the gate dielectric layer, as shown in FIG. 9.
S3: Apply a photoresist (PR) on an upper surface of the polysilicon layer 114, then perform lithography to remove the photoresist between each memory transistor gate region and each selection transistor gate region to expose the polysilicon layer 114, so as to form memory transistor gate region photoresist strips and selection transistor gate region photoresist strips that are spaced apart from one another, where two memory transistor gate region photoresist strips spaced apart on the left and right are formed above the same ONO dielectric layer 111, and two selection transistor gate region photoresist strips spaced apart on the left and right are formed above the same gate oxide layer 112, as shown in FIG. 10.
S4: Perform etching to remove the polysilicon layer 114 exposed by the lithography in step S3, as shown in FIG. 11.
S5: Remove the photoresist by dry etch and/or wet etch to form selection transistor polysilicon gates SG and memory transistor polysilicon gates CG spaced apart from one another, where two memory transistor polysilicon gates CG spaced apart on the left and right are formed above the same ONO dielectric layer 111, and two selection transistor polysilicon gates SG spaced apart on the left and right are formed above the same gate oxide layer 112, as shown in FIG. 12.
S6: Apply a photoresist to cover upper surfaces of the polysilicon layer 114 and the gate dielectric layer, and then perform lithography to remove the photoresist between the two selection transistor polysilicon gates SG adjacent to each other on the left and right, the photoresist on a right part of the left selection transistor polysilicon gate SG, and the photoresist on a left part of the right selection transistor polysilicon gate SG, expose the gate oxide layer 112 between the two selection transistor polysilicon gates SG adjacent to each other on the left and right, and retain the photoresist between the memory transistor polysilicon gates CG, the photoresist between the memory transistor polysilicon gate CG and the selection transistor polysilicon gate SG, and the photoresist above the memory transistor polysilicon gate CG, as shown in FIG. 13.
S7: Perform ion implantation tilted by a set angle on the gate oxide layer 112 covered by no photoresist, so as to form a selection transistor threshold voltage ion implantation region 113, where the selection transistor threshold voltage ion implantation region 113 is located on the surface of the substrate 10 below the gate oxide layer 112 between the selection transistor polysilicon gates SG adjacent to each other on the left and right, below the left part of the right selection transistor polysilicon gate SG, and below the right part of the left selection transistor polysilicon gate SG, as shown in FIG. 14; and tilting the implantation by the set angle can prevent excessive lateral diffusion.
S8: Remove the photoresist by dry etch and/or wet etch, as shown in FIG. 15.
S9: Perform a subsequent process to manufacture the SONOS memory.

In the method for manufacturing a SONOS memory of Embodiment I, the polysilicon layer 114 is first deposited on the surface of the gate dielectric layer, lithography etching is performed to form the selection transistor polysilicon gates SG and the memory transistor polysilicon gates CG that are spaced apart from one another, and then only a region between the selection transistor polysilicon gates SG adjacent to each other on the left and right is opened by lithography. In this way, during ion implantation, the ion implantation region is limited between the selection transistor polysilicon gates SG adjacent to each other on the left and right, and there is no excess selection transistor threshold voltage ion implantation region between the selection transistor polysilicon gate SG and the memory transistor polysilicon gate CG, avoiding a change in a selection transistor threshold voltage Vt and avoiding a leakage, effectively improving the gate-induced drain leakage (GIDL) problem in a selection transistor region, and thereby improving device performance and reliability.

### Embodiment II

Based on the method for manufacturing a SONOS memory of Embodiment I, the ONO dielectric layer 111 is a silicon oxide-silicon nitride-silicon oxide stack layer.

The gate oxide layer 112 is silicon oxide.

### Embodiment III

Based on the method for manufacturing a SONOS memory of Embodiment I, in step S1, a P well is formed on an upper part of the substrate 10, and the gate dielectric layer is formed on the P well of the substrate 10.

In some examples, in step S1, N-type ion implantation is performed on an upper surface of the substrate 10 below the ONO dielectric layer 111 corresponding to the memory transistor polysilicon gate.

In some examples, in step S7, P-type ion (such as boron ion) halo implantation tilted by a set angle is performed at the gate oxide layer 112 covered by no photoresist.

In some examples, a depth of the P-type ion (such as boron ion) halo implantation is 150 Å-200 Å.

In some examples, energy of the P-type ion (such as boron ion) halo implantation is 8 keV-12 keV.

In some examples, a dose of the P-type ion (such as boron ion) halo implantation is 4 E13/cm²-7 E13/cm².

In some examples, the set angle is a lateral included angle of 25°-35° (such as 30°).

The above descriptions are merely examples of the embodiments of the present disclosure and are not intended to limit the present disclosure. Any modifications, equivalent substitutions, improvements, etc. made within the spirit and principles of the present disclosure shall be included within the protection scope of the present disclosure.

What is claimed is:

1. A method for manufacturing a SONOS memory, comprising the following steps:
S1: forming a gate dielectric layer on a substrate, wherein the gate dielectric layer comprises an ONO dielectric layer and a gate oxide layer sequentially adjacent to and spaced apart from each other on the left and right;
S2: growing a polysilicon layer on an upper surface of the gate dielectric layer;
S3: applying a photoresist on an upper surface of the polysilicon layer, then performing lithography to remove the photoresist between each memory transistor gate region and each selection transistor gate region to expose the polysilicon layer, so as to form memory transistor gate region photoresist strips and selection transistor gate region photoresist strips that are spaced apart from one another, wherein two memory transistor gate region photoresist strips spaced apart on the left and right are formed above the same ONO dielectric layer, and two selection transistor gate region photoresist strips spaced apart on the left and right are formed above the same gate oxide layer;
S4: performing etching to remove the polysilicon layer exposed by the lithography;
S5: removing the photoresist to form selection transistor polysilicon gates and memory transistor polysilicon gates spaced apart from one another, wherein two memory transistor polysilicon gates (CG) spaced apart on the left and right are formed above the same ONO dielectric layer, and two selection transistor polysilicon gates (SG) spaced apart on the left and right are formed above the same gate oxide layer;
S6: applying a photoresist to cover upper surfaces of the polysilicon layer and the gate dielectric layer, and then performing lithography to remove the photoresist between the two selection transistor polysilicon gates (SG) adjacent to each other on the left and right, the photoresist on a right part of the left selection transistor polysilicon gate (SG), and the photoresist on a left part of the right selection transistor polysilicon gate (SG), expose the gate oxide layer between the two selection transistor polysilicon gates (SG) adjacent to each other on the left and right, and retain the photoresist between the memory transistor polysilicon gates (CG), the photoresist between the memory transistor polysilicon gate (CG) and the selection transistor polysilicon gate (SG), and the photoresist above the memory transistor polysilicon gate (CG);
S7: performing ion implantation tilted by a set angle on the gate oxide layer covered by no photoresist, so as to form a selection transistor threshold voltage ion implantation region, wherein the selection transistor threshold voltage ion implantation region is located on the surface of the substrate below the gate oxide layer between the selection transistor polysilicon gates (SG) adjacent to each other on the left and right, below the left part of the right selection transistor polysilicon gate (SG), and below the right part of the left selection transistor polysilicon gate (SG);
S8: removing the photoresist; and
S9: performing a subsequent process to manufacture the SONOS memory.

2. The method for manufacturing a SONOS memory according to claim 1, wherein
the ONO dielectric layer is a silicon oxide-silicon nitride-silicon oxide stack layer; and
the gate oxide layer is silicon oxide.

3. The method for manufacturing a SONOS memory according to claim 1, wherein
in step S1, a P well is formed on an upper part of the substrate, and the gate dielectric layer is formed on the P well of the substrate.

4. The method for manufacturing a SONOS memory according to claim 1, wherein
in step S1, N-type ion implantation is performed on an upper surface of the substrate below the ONO dielectric layer corresponding to the memory transistor polysilicon gate.

5. The method for manufacturing a SONOS memory according to claim 1, wherein
in step S7, P-type ion halo implantation tilted by a set angle is performed at the gate oxide layer covered by no photoresist.

6. The method for manufacturing a SONOS memory according to claim 5, wherein
a P-type ion is a boron ion.

7. The method for manufacturing a SONOS memory according to claim 6, wherein
a depth of the P-type ion halo implantation is 150 Å-200 Å.

8. The method for manufacturing a SONOS memory according to claim 6, wherein
energy of the P-type ion halo implantation is 8 keV-12 keV.

9. The method for manufacturing a SONOS memory according to claim 6, wherein
a dose of the P-type ion halo implantation is 4 E13/cm²-7 E13/cm².

10. The method for manufacturing a SONOS memory according to claim 1, wherein
the set angle is a lateral included angle of 25°-35°.
